(19) United States
(12) Patent Application Publication
(10) Pub. No.: US 2024/0203703 A1
(43) Pub. Date: Jun. 20, 2024

(54) SHADOW RING ALIGNMENT FOR SUBSTRATE SUPPORT

(71) Applicant: LAM RESEARCH CORPORATION, Fremont, CA (US)

(72) Inventors: Vinayakaraddy GULABAL, Yadgir (IN); Ravi VELLANKI, San Jose, CA (US); Gary B. LIND, Penn Valley, CA (US); Andrew Paul EIB, Campbell, CA (US)

(21) Appl. No.: 18/287,131

(22) PCT Filed: Apr. 15, 2022
(86) PCT No.: PCT/US2022/025002

§ 371 Date: Oct. 16, 2023

Related U.S. Application Data
(60) Provisional application No. 63/176,683, filed on Apr. 19, 2021.

(51) Int. Cl. H01J 37/32; C23C 16/455; C23C 16/458; H01L 21/687

(52) U.S. Cl. CPC H01J 37/32642; C23C 16/45544; C23C 16/4585; H01L 21/68728; H01L 21/68735; H01J 2237/332

(57) ABSTRACT

A system to align a shadow ring on a substrate support includes a baseplate of the substrate support, an alignment recess defined within an upper surface of the baseplate, a shadow ring, an upper alignment groove defined in a lower surface of the shadow ring, an alignment block disposed within the alignment recess, and an alignment feature disposed between the shadow ring and the alignment block. The alignment feature extends into the upper alignment groove defined in the lower surface of the shadow ring.

### CROSS-REFERENCE TO RELATED APPLICATIONS

This application claims the benefit of U.S. Provisional Application No. 63/176,683, filed on Apr. 19, 2021. The entire disclosures of the applications referenced above are incorporated herein by reference.

### FIELD

The present disclosure relates to alignment of shadow rings in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, etch processes and deposition processes may be performed within a processing chamber. The substrate is disposed in the processing chamber on a substrate support such as an electrostatic chuck (ESC) or a pedestal. Process gases are introduced and, in some examples, plasma is struck in the processing chamber.

Some substrate supports may include a shadow ring. During deposition and etching processes, a substrate is arranged on the substrate support. The shadow ring may be used to protect outer edges of the substrate from deposition and etching. For example, the shadow ring may be raised to facilitate transfer of the substrate to the substrate support and then lowered. An inner diameter of the shadow ring overlaps the outer edge of the substrate.

### SUMMARY

A system to align a shadow ring on a substrate support includes a baseplate of the substrate support, an alignment recess defined within an upper surface of the baseplate, a shadow ring, an upper alignment groove defined in a lower surface of the shadow ring, an alignment block disposed within the alignment recess, and an alignment feature disposed between the shadow ring and the alignment block. The alignment feature extends into the upper alignment groove defined in the lower surface of the shadow ring.

In other features, the alignment recess and the alignment block have an interlocking arrangement. The alignment recess and the alignment block have complementary shapes. Each of the alignment recess and the alignment block is “T”-shaped. The alignment recess receives the alignment block from a radially outward direction relative to the substrate support. The alignment block includes a vertical channel and a pin is disposed within the vertical channel. The pin extends from the baseplate below the alignment block into the upper alignment groove. The pin is located radially inward of the alignment feature. The pin is located radially outward of the alignment feature.

In other features, the upper alignment groove is generally rectangular. The lower alignment groove is semicircular. The alignment feature includes a wheel. The alignment block includes a slot that is perpendicular to the lower alignment groove and receives a lower portion of the wheel. A lower alignment groove is defined in an upper surface of the alignment block, the alignment feature includes a shaft coupled to the wheel, and the shaft is aligned with the lower alignment groove.

In other features, the system further includes a controller to lower the shadow ring onto the alignment feature. The system further includes a plurality of the alignment recesses, the alignment blocks, and the alignment features. The system further includes three of the alignment recesses.

A system to align a shadow ring on a substrate support includes a baseplate of the substrate support, an alignment recess defined within an upper surface of the baseplate, a shadow ring, an upper alignment groove defined in a lower surface of the shadow ring, an alignment block disposed within and having an interlocking arrangement with the alignment recess, a lower alignment groove defined in an upper surface of the alignment block, a pin extending from the baseplate and through the alignment block, and an alignment feature disposed between the shadow ring and the alignment block. The alignment features extends into the upper alignment groove defined in the lower surface of the shadow ring and into the lower alignment groove.

In other features, the alignment recess and the alignment block have complementary shapes. Each of the alignment recess and the alignment block is “T”-shaped. The alignment recess receives the alignment block from a radially outward direction relative to the substrate support. The alignment block includes a vertical channel and the pin is disposed within the vertical channel. The alignment feature includes a wheel. The alignment block includes a slot that is perpendicular to the lower alignment groove and receives a lower portion of the wheel.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of a substrate processing system including an example shadow ring according to the present disclosure;

FIG. 1B shows an example shadow ring in a lowered position according to some embodiments of the present disclosure;

FIG. 1C shows an example shadow ring in a raised position according to some embodiments of the present disclosure;

FIG. 1D is a plan view of a shadow ring according to some embodiments of the present disclosure;

FIG. 2A is a side view of an example shadow ring alignment assembly according to some embodiments of the present disclosure;

FIG. 2B is an isometric view of the shadow ring alignment assembly of FIG. 2A;

FIG. 2C is a side view of another example shadow ring alignment assembly according to some embodiments of the present disclosure;

FIG. 2D is an isometric view of the shadow ring alignment assembly of FIG. 2C;

FIG. 2E is a plan view of the shadow ring alignment assembly of FIG. 2A;

FIG. 2F shows a bottom view of an example shadow ring according to some embodiments of the present disclosure;

FIG. 2G is an isometric view of the shadow ring of FIG. 2F;

FIG. 3A is a side view of another example shadow ring alignment assembly according to some embodiments of the present disclosure;

FIG. 3B is an isometric view of the shadow ring alignment assembly of FIG. 3A;

FIG. 4A is an example substrate support that includes lift pins configured to center a substrate and shadow ring according to the present disclosure;

FIG. 4B shows the lift pins of FIG. 4A;

FIG. 4C is an isometric view of a portion of the substrate support of FIG. 4A;

FIGS. 4D, 4E, 4F, and 4G show an example process for centering the substrate and the shadow ring on the substrate support according to the present disclosure;

FIGS. 4H and 41 show an example alignment bracket for the lift pins according to the present disclosure;

FIG. 5 shows another example substrate support according to the present disclosure;

FIGS. 6A, 6B, and 6C show other example lift pin configurations according to the present disclosure.

In the drawings, reference numbers may be reused to identify similar and/or identical elements.

### DETAILED DESCRIPTION

A substrate support may include a shadow ring to protect outer edges of a substrate from deposition and etching during processing. In examples where the shadow ring is used to prevent deposition (e.g., tungsten deposition) on the outer edges of the substrate, a purge gas may be supplied between the shadow ring and the substrate to reduce species concentration at the edge of the substrate and further reduce deposition.

The shadow ring may be configured to be raised and lowered, and may transferred to and from the substrate support. Accordingly, various techniques may be used to align (e.g., center) the shadow ring relative to the substrate support. For example, the shadow ring may be aligned with the substrate support using mechanical components such as screws (e.g., ceramic or metal screws), nuts, springs, wheels, etc. These mechanical components susceptible to failures caused by corrosion, fractures, high temperatures (e.g., damage associated with the presence of fluorine at temperatures above 400° C.), etc.

Shadow ring alignment systems and methods according to the present disclosure implement various features to facilitate alignment while reducing or eliminating mechanical components as described below in more detail.

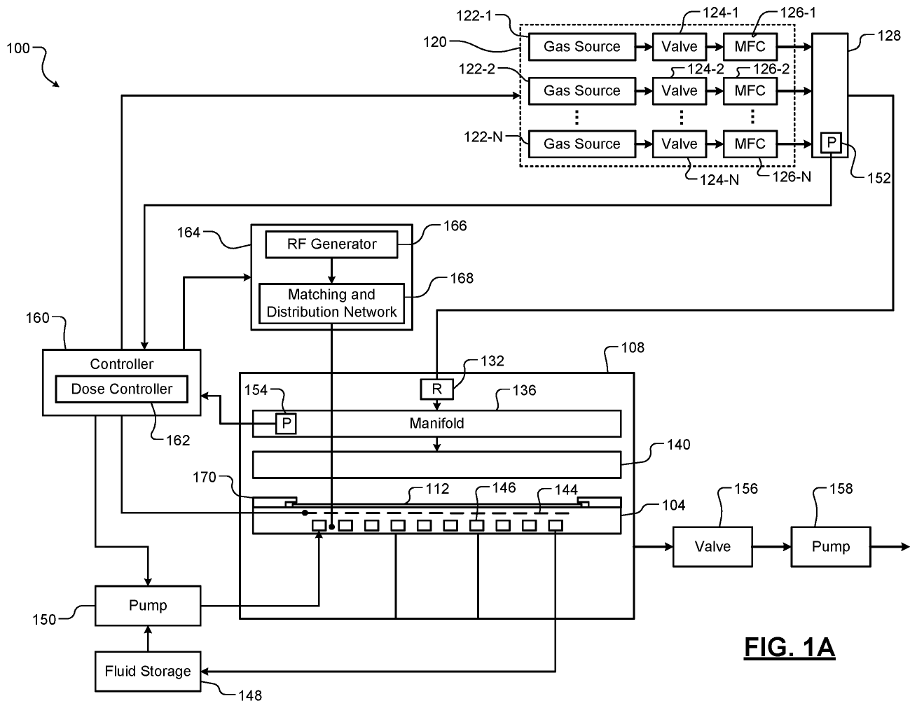

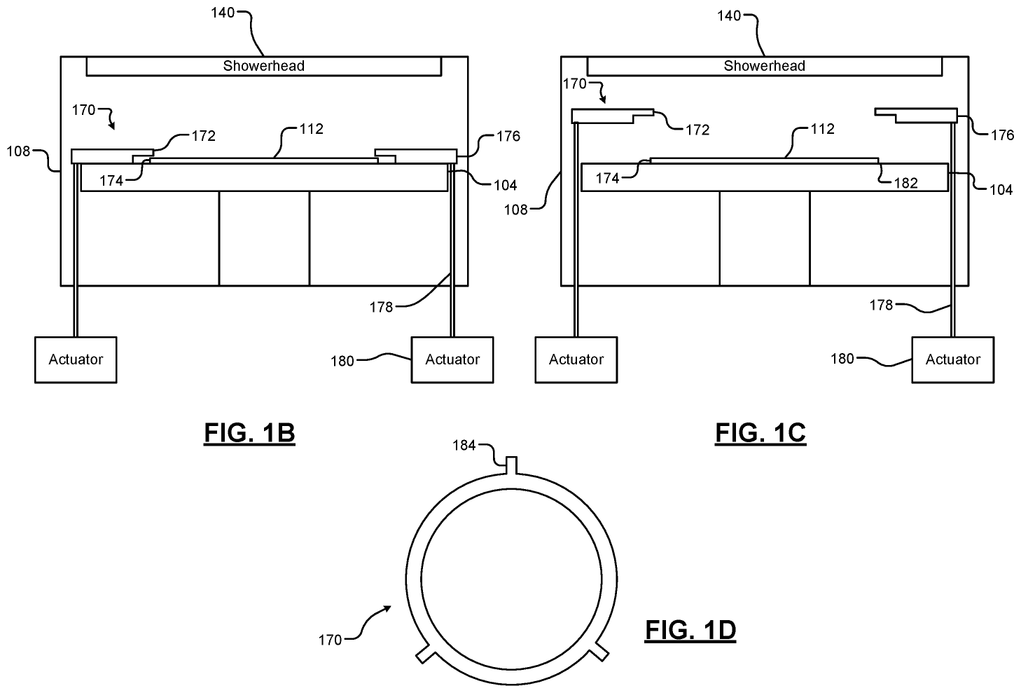

Referring now to FIG. 1A, an example of a substrate processing system 100 including a substrate support (e.g., a pedestal configured for CVD and/or ALD deposition) 104 according to the present disclosure is shown. The substrate support 104 is arranged within a processing chamber 108. A substrate 112 is arranged on the substrate support 104 during processing. For example, deposition is performed on the substrate 112. The substrate 112 is removed and one or more additional substrates are treated.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a manifold 136. An output of the manifold 136 is input to a gas distribution device such as a multi-injector showerhead 140. While the manifold 128 and 136 are shown, a single manifold can be used.

In some examples, a temperature of the substrate support 104 may be controlled using resistive heaters 144. The substrate support 104 may include coolant channels 146. Cooling fluid is supplied to the coolant channels 146 from a fluid storage 148 and a pump 150. Pressure sensors 152, 154 may be arranged in the manifold 128 or the manifold 136, respectively, to measure pressure. A valve 156 and a pump 158 may be used to evacuate reactants from the processing chamber 108 and/or to control pressure within the processing chamber 108.

A controller 160 includes a dose controller 162 that controls dosing provided by the multi-injector showerhead 140. The controller 160 also controls gas delivery from the gas delivery system 120. The controller 160 controls pressure in the processing chamber and/or evacuation of reactants using the valve 156 and the pump 158. The controller 160 controls the temperature of the substrate support 104 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 108 as deposition processes. Accordingly, the substrate processing system 100 may include an RF generating system 164 configured to generate and provide RF power (e.g., as a voltage source, current source, etc.) to one of a lower electrode (e.g., a baseplate of the substrate support 104, as shown) and an upper electrode (e.g., the showerhead 140). The other one of the lower electrode and the upper electrode may be DC grounded, AC grounded or floating.

For example only, the RF generating system 164 may include an RF generator 166 configured to generate the RF voltage that is fed by a matching and distribution network 168 to generate plasma within the processing chamber 108 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

Referring now to FIGS. 1B and 1C and with continued reference to FIG. 1A, the substrate support 104 includes a shadow ring 170. An inner edge 172 of the shadow ring 170 overlaps an outer edge 174 of the substrate 112 to protect the outer edge 174 from deposition and/or etching. In some examples, an outer edge 176 of the shadow ring 170 may extend over an outer edge of the substrate support 104. In other words, an outer diameter of the shadow ring 170 is greater than an outer diameter of the substrate support 104. Accordingly, in some implementations, a portion of the shadow ring 170 extends over the substrate support 104 and can be engaged by one or more lift pins 178. In other examples, the lift pins 178 may extend through the substrate support 104. In other examples, an index plate is used to raise shadow ring 170.

Actuators 180 (e.g., linear actuators responsive to the controller 160) raise and lower the lift pins 178 to raise and lower the shadow ring 170. As shown in FIGS. 1B and 1C, the shadow ring 170 is configured to be moved between a lowered position (as shown in FIG. 1B) and a raised position (as shown in FIG. 1C). In the lowered position, the inner edge 172 of the shadow ring 170 overlaps the substrate 34 and protects the outer edge 174 of the substrate 112 as described above.

In some embodiments, the shadow ring 170 includes arms or tabs 184 extending radially outward from the shadow ring 170 as shown in a plan view in FIG. 1D. In some embodiments, the shadow ring 170 includes three of the tabs 184. In some embodiments, the shadow ring 170 includes fewer than (e.g., two) or more than three of the tabs 184. The tabs 184 extend over the outer edge of the substrate support 104. In other words, an outer diameter defined by the tabs 184 may be greater than the outer diameter of the substrate support 104. In some embodiments, the shadow ring 170 may be retrieved (e.g., by a robot, a lifting or index ring, etc.) using the tabs 184. In other embodiments, the tabs 184 may extend over the substrate support 104 and are aligned with the lift pins 178. In this manner, the tabs 184 can be engaged by the lift pins 178 to raise and lower the shadow ring 170.

The substrate support 104 and shadow ring 170 according to the present disclosure implement alignment features as described below in more detail.

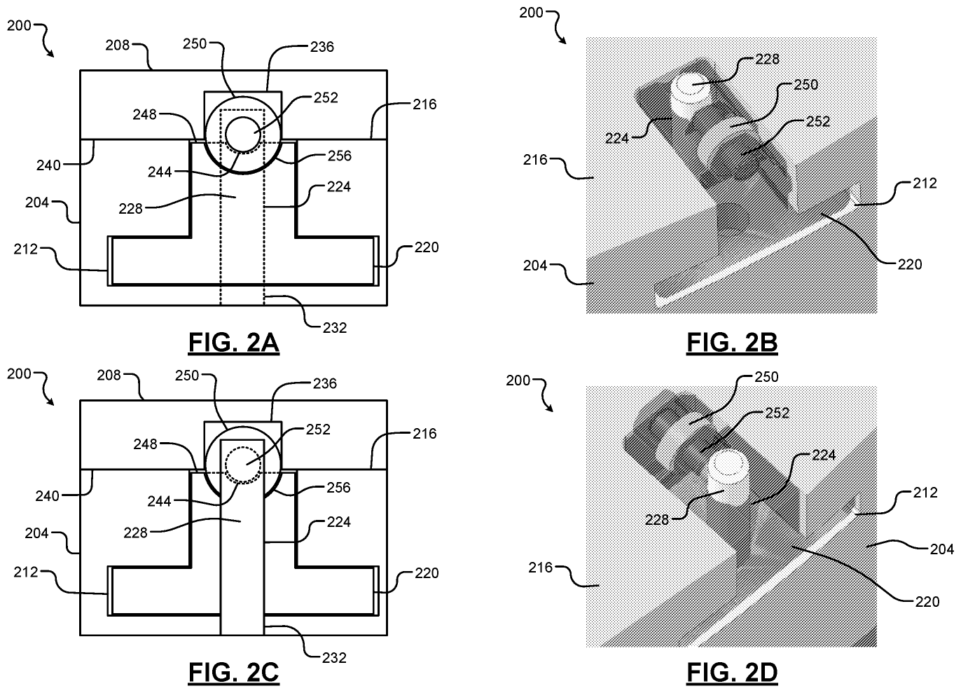

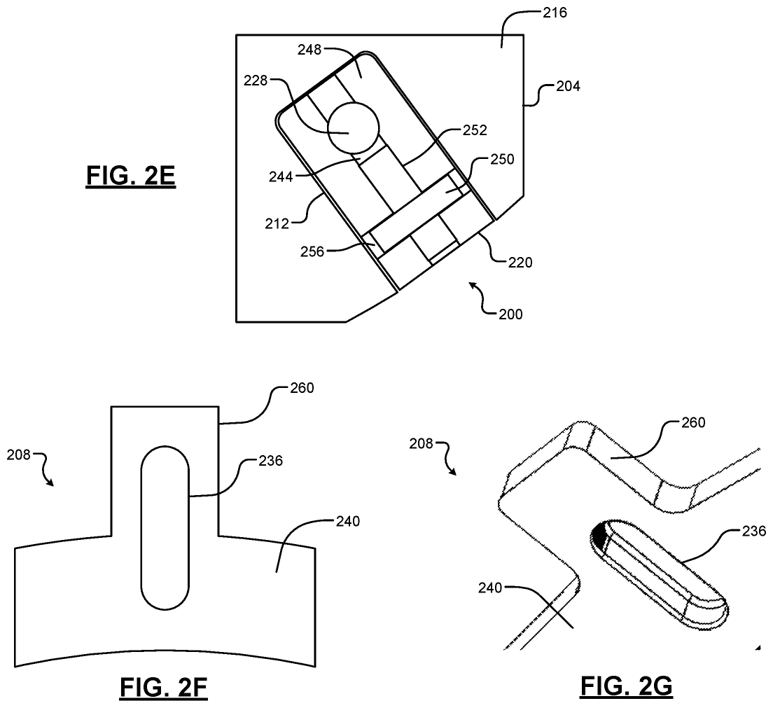

Referring now to FIGS. 2A, 2B, 2C, and 2D, a side view (i.e., a view looking radially inward from an outer perimeter as shown in FIGS. 2A and 2B) and an isometric view (in FIGS. 2C and 2D) of an example shadow ring alignment assembly 200 (e.g., of a substrate support assembly) according to the present disclosure is shown. A baseplate 204 supports a shadow ring 208. The baseplate 204 may be conductive (e.g., comprised of metal, such as aluminum). One or more alignment recesses 212 (e.g., a cavities or grooves) are defined within an upper surface 216 of the baseplate 204. For example only, the baseplate 204 includes three of the alignment recesses 212 circumferentially spaced apart at 120 degree intervals. In some examples, one of the alignment recesses 212 may be offset from the 120 degree interval (e.g., by 10 degrees). As shown, the alignment recess is “T”-shaped (e.g., has an inverted “T” shape), but other suitable shapes may be used.

An alignment block 220 is disposed within the alignment recess 212. For example, the alignment block 220 has a shape that is complementary to the shape of the alignment recess 212. As shown, the alignment block 220 is “T”-shaped. Accordingly, the alignment recess 212 and the alignment block 220 have an interlocking arrangement relative to one another. The alignment block 220 may be insertably received within the alignment recess 212 from a radially outward direction. Conversely, the interlocking arrangement of the alignment block 220 within the alignment recess 212 prevents lateral and upward movement of the alignment block 220 relative to the baseplate 204. For example only, the alignment block 220 is comprised of a dielectric material (e.g., alumina or another ceramic).

The alignment block 220 includes a vertical via or channel 224. A pin 228 is arranged in the channel 224. For example, the pin 228 extends upward from a corresponding channel 232 in the baseplate 204, through the alignment block 220, and into an upper alignment groove (e.g., a generally rectangular groove) 236 defined in a lower surface 240 of the shadow ring 208. The upper alignment groove 236 extends in a radial direction relative to the baseplate 204. The pin 228 fixes a position of the alignment block 220 relative to the alignment recess 212 and the baseplate 204. For example, the pin 228 prevents movement of the alignment block 220 in lateral and radial directions. The pin 228 is comprised of a dielectric material such as ceramic.

A lower alignment groove (e.g., a semicircular groove) 244 is defined in an upper surface 248 of the alignment block 220. The lower alignment groove 244 extends in a radial direction relative to the baseplate 204. The lower alignment groove 244 is aligned with the upper alignment groove 236 (e.g., in a radial direction). The lower alignment groove 244 and the upper alignment groove 236 are configured to receive and retain an alignment feature arranged between the alignment block 220 and the shadow ring 208, such as an alignment disc or wheel 250. The wheel 250 is coupled to an axle or shaft 252. The wheel 250 and the shaft 252 are comprised of a dielectric material such as ceramic. In other examples, the alignment feature extends upward from the alignment block 220.

In some examples, the wheel 250 is configured to rotate within the alignment block 220 on an axis defined by the shaft 252. For example, as shown in FIG. 2E, the alignment block 220 includes a recess or slot 256 that is perpendicular to the lower alignment groove 244. The shaft 252 is aligned with and disposed within the lower alignment groove 244. The slot 256 is configured to receive a lower portion of the wheel 250. The slot 256 allows the wheel 250 to rotate within the alignment block 220. As shown in FIGS. 2A, 2B, and 2E, the shaft 252 and the wheel 250 are located radially outward of the pin 228. Conversely, as shown in FIGS. 2C and 2D, the pin 228 is located radially outward of the shaft 252 and the wheel 250.

As shown in more detail in FIGS. 2F and 2GF, the upper alignment grooves 236 extend in a radially outward direction relative to the shadow ring 208 and the baseplate 204. Accordingly, the upper alignment groves 236 are configured to align with the pin 228 and the wheel 250 of respective alignment blocks 220. In some examples, the shadow ring 208 includes two or more (e.g., three) arms 260 extending radially outward from the shadow ring 208. The upper alignment grooves 236 may be aligned with the arms 260 such that the upper alignment grooves 236 extend from a body of the shadow ring 208 into the arms 260.

The pin 228 and the wheel 250 are configured to align (e.g., center) the shadow ring 208 on the baseplate 204. For example, a substrate is arranged on the baseplate 204 (e.g., with the shadow ring 208 in a raised position as shown in FIG. 1C). The shadow ring 208 is then lowered onto the baseplate 204. For example, the shadow ring 208 is lowered using an index plate configured to interface with the arms 260. As the shadow ring 208 is lowered, the upper alignment grooves 236 contact respective ones of the wheels 250. The contact between the wheels 250 and the upper alignment grooves 236 cause the shadow ring 208 to rotate until each of the upper alignment grooves 236 is centered relative to the respective wheels 250 and pins 228. When in a completely lowered position, each of the pins 228 is received within the upper alignment grooves 236 and prevents additional rotational movement of the shadow ring 208.

Conversely, the orientation of the upper alignment grooves 236 allows movement of the pins 228 in the radial direction. In other words, the pins 228 are allowed to move within the upper alignment grooves in a radial inward direction and a radial outward direction relative to the shadow ring. For example, the baseplate 204 may be comprised of a metal such as aluminum that expands and contracts with changes in temperature. The pins 228 move radially outward and inward as the baseplate 204 expands and contracts, respectively. Accordingly, expansion and contraction of the baseplate 204 do not cause misalignment of the shadow ring 208, damage to the shadow ring 208, etc.

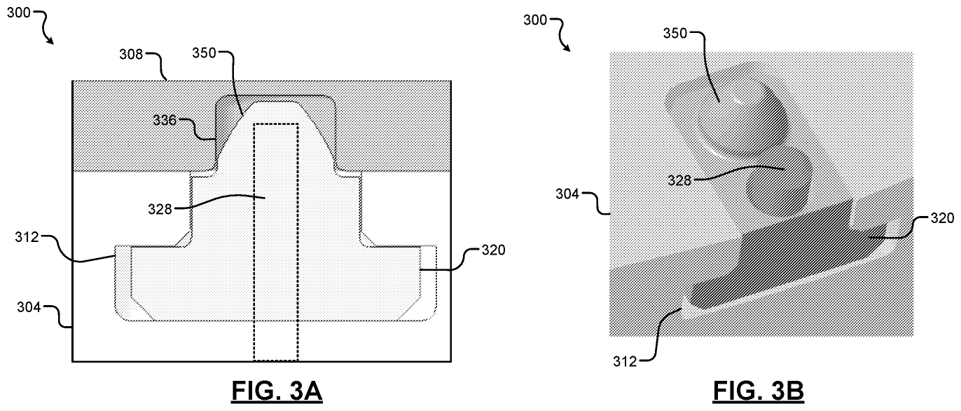

Another example shadow ring alignment assembly 300 (e.g., of a substrate support) according to the present disclosure is shown in FIGS. 3A and 3B. The shadow ring alignment assembly 300 includes a baseplate 304 that supports a shadow ring 308. One or more (e.g., three) alignment recesses 312 are defined within the baseplate 304. An alignment block 320 disposed within the alignment recess 312 has a shape that is complementary to the shape of the alignment recess 312. A pin 328 extends upward from the baseplate 304, through the alignment block 320, and into an upper alignment groove 336 defined in a lower surface of the shadow ring 308.

The alignment block 320 includes an alignment feature 350. In this example, the alignment feature 350 extends upward from the alignment block 320 into the upper alignment groove 336. The alignment feature 350 may be integrally formed with the alignment block 320. The alignment feature 350 may be conical, rounded, etc. to facilitate alignment of the shadow ring 308 on the baseplate 304.

A lower alignment groove (e.g., a semicircular groove) 244 is defined in an upper surface 248 of the alignment block 220. The lower alignment groove 244 extends in a radial direction relative to the baseplate 204. The lower alignment groove 244 is aligned with the upper alignment groove 236 (e.g., in a radial direction). The lower alignment groove 244 and the upper alignment groove 236 are configured to receive and retain an alignment mechanism, such as an alignment disc or wheel 250. The wheel 250 is coupled to an axle or shaft 252. The wheel 250 and the shaft 252 are comprised of a dielectric material such as ceramic.

Shadow ring alignment systems and methods according to the present disclosure may further implement lift pins configured to align the substrate and shadow ring as described below in more detail.

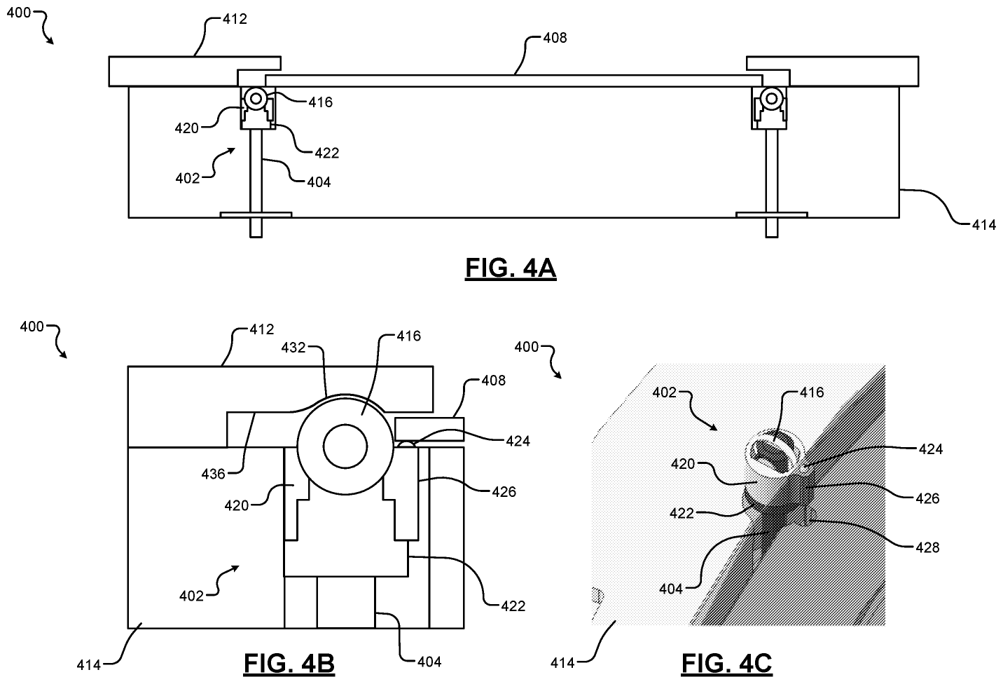

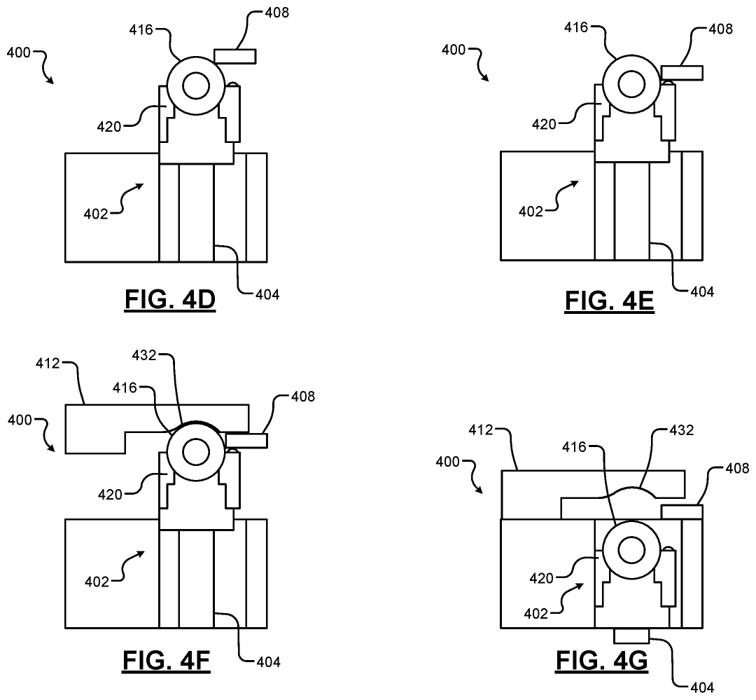

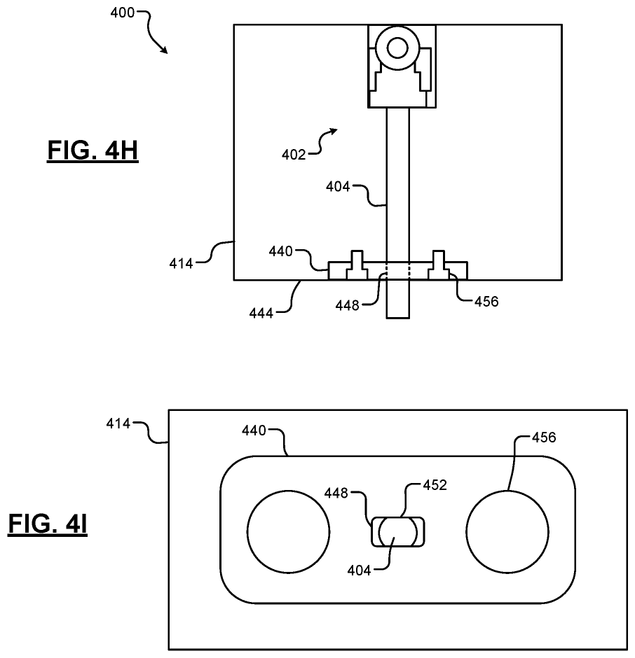

Referring now to FIGS. 4A, 4B, and 4C, an example substrate support 400 according to the present disclosure includes lift pin assemblies 402 comprising lift pins 404 configured to center a substrate 408 and a shadow ring 412. For example, the substrate support 400 includes three of the lift pins 404 circumferentially spaced apart at 120 degree intervals. In some example, the lift pins 404 may be aligned in a radial direction with respective ones of the alignment blocks 220 as described above. The lift pins 404 extend through a baseplate 414 in respective locations radially outward of an outer perimeter of the substrate 408. The lift pins 404 include wheels 416. For example, the lift pins 404 and wheels 416 may be comprised of sapphire. The wheels 416 are configured to rotate in a radial direction relative to the substrate support 400. Accordingly, as the substrate 408 is lowered onto the lift pins 404, the wheels 416 bias the substrate radially inward into a centered position relative to the substrate support 400.

An outer edge of the substrate 408 is supported on a sleeve 420 disposed around a flange 422 on an upper end of the lift pin 404. The flange 422 may be comprised of ceramic. For example, the sleeve 420 may include a minimum contact area feature (such as a bump 424) configured to support the substrate 408. As shown in FIG. 4C, the sleeve 420 may include a projection 426 that extends into a notch 428 in the substrate support 400. The projection 426 and the notch 428 prevent rotation of the lift pins 404. The bump 424 may be disposed on the projection 426.

The shadow ring 412 can then be lowered onto the lift pins 404. For example, the shadow ring 412 includes centering features such as tapered slots or ramps 432 on a lower surface 436 of the shadow ring 412. Although shown as indentations or notches in the lower surface 436 of the shadow ring 412, in other examples the ramps 432 may be configured as protrusions or projections extending downward from the lower surface 436. As the shadow ring 412 is lowered onto the wheels 416, the ramps 432 receive respective ones of the wheels 416. Contact between the ramps 432 and the wheels 416 biases the shadow ring 412 into a centered position relative to the substrate support 400. With the substrate 408 supported on the sleeve 420 and the shadow ring 412 supported on the wheels 416, the lift pins 404 are lowered to lower the substrate 408 and the shadow ring 412 onto the substrate support 400. In this manner, the lift pins 404 and the wheels 416 are configured to center both the substrate 408 and the shadow ring 412 relative to each other and the substrate support 400.

An example process for centering the substrate 408 and the shadow ring 412 on the substrate support 400 according to the present disclosure is shown in FIGS. 4D, 4E, 4F, and 4G. As shown in FIG. 4D, the substrate 408 is lowered onto the wheels 416 with the lift pins 404 in a raised position. As shown in FIG. 4E, the substrate 408 slides radially inward on the wheels 416 (and/or the wheels 216 rotate) to be supported on the sleeve 420. Accordingly, the substrate 408 is centered relative to the arrangement of the lift pins 404 and the substrate support 400. As shown in FIG. 4F, the shadow ring 412 is lowered onto the wheels 416. Accordingly, the shadow ring 308 is centered relative to the substrate 408. As shown in FIG. 4G, the lift pins 404 are lowered to lower the substrate 408 and the shadow ring 412 onto the substrate support 400.

Referring not to FIGS. 4H and 41, the substrate support 400 may include alignment brackets 440. FIG. 41 shows a plan view of one of the alignment brackets 440. As shown, the alignment brackets 440 are arranged in a lower surface 444 of the baseplate 414. The alignment brackets 440 are configured to retain and align the lift pins 404. For example, portions of the lift pins 404 passing through rectangular openings 448 in the alignment brackets 440 include one or more flat sides 452. Accordingly, the configuration of the openings 448 prevents rotation of the lift pins 404. The alignment brackets 440 may be secured to the baseplate 414 using fasteners such as screws 456.

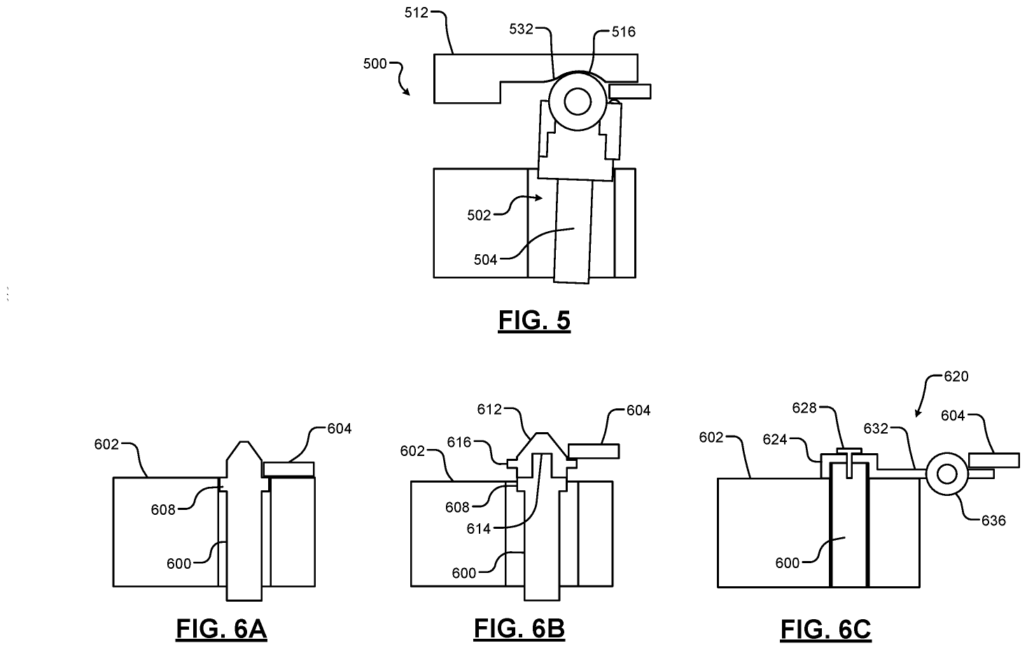

FIG. 5 shows another example substrate support 500 according the present disclosure. The substrate support 500 includes a lift pin assembly 502. The lift pin assembly 502 includes a lift pin 504 configured to center a substrate 508 and shadow ring 512 a wheel 516. In this example, the lift pin assembly 502 (e.g., the lift pin 504 and the wheel 516 are configured to tilt radially inward when the shadow ring 512 is lowered onto the wheel 516. For example, a tapered slot or ramp 532 defined in a lower surface of the shadow ring 512 may bias the lift pin 504 radially inward as the shadow ring 512 is lowered onto the wheel 516.

FIGS. 6A, 6B, and 6C show other example lift pins 600 of a substrate support 602 according to the present disclosure. As shown in FIG. 6A, an upper end of the lift pin 600 is rounded or tapered. As a substrate 604 is lowered onto the lift pin 600, the substrate 604 is biased radially inward by the tapered upper end of the lift pin 600. When centered, the substrate 604 is supported on an annular rim or flange 608 encircling the lift pin 600. When the lift pin 600 is lowered, the substrate 604 is supported on the substrate support 602.

As shown in FIG. 6B, the lift pin 600 includes a removable and replaceable cap 612. The cap 612 includes an inner cavity 614 configured to receive an upper end of the lift pin 600. An upper surface of the cap 612 is rounded or tapered. Accordingly, as the substrate 604 is lowered onto the lift pin 600, the substrate 604 is biased radially inward by the tapered upper surface of the cap 612. The cap 612 includes an annular ledge 616 that supports the substrate 604.

As shown in FIG. 6C, the lift pin 600 includes a wheel assembly 620. The wheel assembly 620 includes a wheel clip 624 configured to receive and be supported upon an upper end of the lift pin 600. For example, the wheel clip 624 is fastened to the lift pin 600 using a screw 628. The wheel clip 624 includes a flange 632 that extends radially inward from the lift pin 600. The flange 632 is configured to retain a wheel 636. Accordingly, as the substrate 604 is lowered onto the wheel 636, the substrate 604 is biased radially inward by the wheel 636.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system to align a shadow ring on a substrate support, the system comprising:
a baseplate of the substrate support;
an alignment recess defined within an upper surface of the baseplate;
a shadow ring;
an upper alignment groove defined in a lower surface of the shadow ring;
an alignment block disposed within the alignment recess; and
an alignment feature disposed between the shadow ring and the alignment block, wherein the alignment feature extends into the upper alignment groove defined in the lower surface of the shadow ring.

2. The system of claim 1, wherein the alignment recess and the alignment block have an interlocking arrangement.

3. The system of claim 1, wherein the alignment recess and the alignment block have complementary shapes.

4. The system of claim 1, wherein each of the alignment recess and the alignment block is “T”-shaped.

5. The system of claim 1, wherein the alignment recess receives the alignment block from a radially outward direction relative to the substrate support.

6. The system of claim 1, wherein the alignment block includes a vertical channel and a pin is disposed within the vertical channel, and wherein the pin extends from the baseplate below the alignment block into the upper alignment groove.

7. The system of claim 6, wherein the pin is located radially inward of the alignment feature.

8. The system of claim 6, wherein the pin is located radially outward of the alignment feature.

9. The system of claim 1, wherein the upper alignment groove is generally rectangular.

10. The system of claim 1, wherein the lower alignment groove is semicircular.

11. The system of claim 1, wherein the alignment feature includes a wheel.

12. The system of claim 11, wherein the alignment block includes a slot that is perpendicular to the lower alignment groove and receives a lower portion of the wheel.

13. The system of claim 11, wherein a lower alignment groove is defined in an upper surface of the alignment block, the alignment feature includes a shaft coupled to the wheel, and the shaft is aligned with the lower alignment groove.

14. The system of claim 1, further comprising a controller to lower the shadow ring onto the alignment feature.

15. The system of claim 1, further comprising a plurality of the alignment recesses, the alignment blocks, and the alignment features.

16. The system of claim 1, further comprising three of the alignment recesses.

17. A system to align a shadow ring on a substrate support, the system comprising:
a baseplate of the substrate support;
an alignment recess defined within an upper surface of the baseplate;
a shadow ring;
an upper alignment groove defined in a lower surface of the shadow ring;
an alignment block disposed within and having an interlocking arrangement with the alignment recess;
a lower alignment groove defined in an upper surface of the alignment block;
a pin extending from the baseplate and through the alignment block; and
an alignment feature disposed between the shadow ring and the alignment block, wherein the alignment features extends into the upper alignment groove defined in the lower surface of the shadow ring and into the lower alignment groove.

18. The system of claim 17, wherein the alignment recess and the alignment block have complementary shapes.

19. The system of claim 17, wherein each of the alignment recess and the alignment block is “T”-shaped.

20. The system of claim 17, wherein the alignment recess receives the alignment block from a radially outward direction relative to the substrate support.

21. The system of claim 17, wherein the alignment block includes a vertical channel and the pin is disposed within the vertical channel.

22. The system of claim 17, wherein the alignment feature includes a wheel.

23. The system of claim 22, wherein the alignment block includes a slot that is perpendicular to the lower alignment groove and receives a lower portion of the wheel.
